(19) United States
(12) Patent Application Publication
(10) Pub. No.: US 2026/0365056 A1
(43) Pub. Date: Nov. 19, 2026

(54) STATIONARY INDUCTION CHARGING DEVICE AND INDUCTIVE VEHICLE CHARGING SYSTEM WITH THE SAME

(71) Applicant: MAHLE International GmbH, Stuttgart (DE)

(72) Inventors: Mike Boettigheimer, Kornwestheim (DE); Stefan Hirsch, Stuttgart (DE); Christopher Laemmle, Stuttgart (DE); Timo Laemmle, Kernen (DE)

(21) Appl. No.: 19/136,850

(22) PCT Filed: Dec. 1, 2023
(86) PCT No.: PCT/EP2023/084010

§ 371 Date: Jun. 6, 2025

(30) Foreign Application Priority Data
Dec. 9, 2022 (DE) 10 2022 213 360.9

(51) Int. Cl. B60L 53/302; B60L 53/124; B60L 53/36; B60L 53/38; H02J 50/00; H05K 7/20

(52) U.S. Cl. CPC B60L 53/302; B60L 53/124; B60L 53/36; B60L 53/38; H02J 50/005; H05K 7/20127; H05K 7/20409

(57) ABSTRACT

The present invention relates to a stationary induction charging device (4) for an inductive vehicle charging system (2), which has a housing (5) comprising a base plate (6) and a lid (7) arranged thereon, wherein the base plate (6) has a collar (8) which projects beyond the lid (7). The induction charging device (4) also has an inductive charging device (9) which is arranged within an interior space (10) of the housing (5) bounded by the base plate (6) and the lid (7) in thermal contact with the base plate (6) and is designed for electromagnetic interaction with an induction charging device (11) assigned to the battery-electric vehicle (1), so that electrical energy can be transferred inductively from the stationary induction charging device (4) to the battery-powered vehicle (1) and vice versa, and a cooling device (13) which is in thermal contact with the collar (8) and is designed to dissipate heat energy from the base plate (6) to the ambient air (47). The invention relates in particular to an inductive vehicle charging system (2) with such a stationary induction charging device (4).

The invention relates to a stationary induction charging device according to the subject matter of claim 1. The invention relates in particular to an inductive vehicle charging system with a stationary induction charging device of this kind.

Inductive vehicle charging systems for charging battery-powered vehicles have stationary induction charging devices that can be installed on a ground such as the floor of a garage or parking lot. In practice, these are also referred to as GA (ground assembly). They are designed for electromagnetic interaction with an induction charging device assigned to the battery electric vehicle, which is designated as VA (Vehicle assembly), so that electrical energy can be transferred from the vehicle charging system to the battery electric vehicle and vice versa. During operation, heat is lost in the stationary induction charging device, which poses a risk of overheating, especially at high ambient temperatures.

The objective of the invention is therefore to provide an improved or at least a different embodiment of a stationary induction charging device and/or an improved inductive vehicle charging system for charging a battery-powered vehicle with electrical energy.

In the present invention, this task is solved in particular by the subject matter of the independent claims. Advantageous embodiments are the subject of the dependent claims and the description.

The basic idea behind the invention is to increase the cooling capacity achievable at a stationary induction charging device of an inductive vehicle charging system as dissipatable heat per unit of time by means of a cooling device arranged on the stationary induction charging device and designed for convective heat dissipation.

Accordingly, a stationary induction charging device that can be fixedly arranged on a ground is proposed for an inductive vehicle charging system designed to charge a battery-powered vehicle with electrical energy, which comprises at least the following
a housing comprising a base plate and a lid arranged thereon, wherein the base plate has a collar which projects beyond the lid and surrounds it at least in sections,
an inductive charging device, which is arranged within an interior space of the housing bounded by the base plate and the lid in thermal contact with the base plate and is designed for electromagnetic interaction with an induction charging device assigned to the battery-powered vehicle, so that electrical energy can be transferred from the stationary induction charging device to the battery-powered vehicle and vice versa, and
a cooling device that is designed to convectively dissipate heat from the base plate to the ambient air surrounding the stationary induction charging device and is in thermal contact with the collar.

During operation of the stationary induction charging device, losses in the form of heat occur, particularly at the inductive charging device. This heat is mainly conducted into the base plate and dissipated from there by convection to the ambient air on the one hand and by heat conduction to the ground on the other. This allows relatively effective temperature control of the stationary induction charging device to be achieved. However, the achievable heat transfer per unit of time, i.e., the cooling capacity, is proportional to the temperature difference between the base plate on the one hand and the ambient air and the ground on the other. Accordingly, as the ambient temperature rises and the temperature difference between the base plate, the ambient air, and the ground decreases, the amount of heat that can be dissipated per unit of time continuously decreases, which, especially at high ambient temperatures, poses a risk of overheating the stationary induction charging device and thus destroying it. To avoid this, the transmission power of the stationary induction charging device is currently reduced when a specified transmission power is requested by the stationary induction charging device and a certain ambient temperature is reached or exceeded. This results in less heat loss in the stationary induction charging device, so that overheating can be avoided with the given amount of heat that can be dissipated per unit of time. However, due to the reduced transmission power, less electrical energy can be transferred from the stationary induction charging device to the battery electric vehicle, i.e., to the vehicle-side induction charging device, which in particular significantly increases the charging time required to charge a battery of the battery electric vehicle, which reduces customer comfort when charging the battery electric vehicle due to the longer waiting times. Since these disadvantages are undesirable, the invention proposes increasing the heat that can be dissipated per unit of time by supplementing the stationary induction charging device with a cooling device that is designed to convectively dissipate heat from the base plate to the ambient air, is in thermal contact with the collar of the base plate, and is arranged in particular so as to be in contact with the same. This ensures that the stationary induction charging device is adequately temperature-controlled even at relatively high ambient temperatures. This has the advantage that the stationary induction charging device can be operated even at relatively high ambient temperatures without reducing the transmission power.

It is advisable for the cooling device to be assigned to the collar in such a way that it is located outside the housing, i.e., not within the interior space of the housing, and is also in thermal contact with the ambient air. The cooling device can, for example, be arranged in contact with the collar, i.e., directly supported, or with the interposition of a heat transfer medium, such as heat transfer paste or the like. Optionally, the base plate could be designed as a fluid-cooled cooling plate so that heat generated by the inductive charging device can be better conducted through the base plate to the collar. Furthermore, it is useful if the inductive charging device comprises an energy coil for providing an electromagnetic field and/or power electronics. The power electronics can alternatively be housed in a device of the inductive vehicle charging system that is separate from the stationary induction charging device and can be arranged on a ground.

It may be useful to provide that the cooling device is made of electrically conductive material. This may be metallic material, in particular aluminum. The cooling device is preferably made entirely or at least in sections from this material. A suitable cooling device can be manufactured relatively inexpensively and is ideal for convective heat dissipation. In addition, a corresponding cooling device can specifically influence an electromagnetic field provided by an energy coil of the inductive charging device for transferring energy. For example, it can conduct or shield the electromagnetic field. Furthermore, an electromagnetic field of a remote positioning device of the stationary induction charging device, which supports or realizes the approach of the battery electric vehicle to a target charging position in the inductive vehicle charging system, can be detected by means of the correspondingly designed cooling device, and an electromagnetic field of a live object detection device of the stationary induction charging device set up to detect live objects located in the vicinity of the stationary induction charging device, for example between the stationary induction charging device and the vehicle-side induction charging device, are influenced, in particular guided or shielded.

It may also be useful to provide that the cooling device has a rectangular, L-shaped, rectangular ring-shaped, or square ring-shaped contour when viewed perpendicular to the base plate.

It may be expedient to provide that the cooling device is formed by cooling fins. The cooling fins are conveniently designed separately, arranged parallel to each other and/or at equal distances from each other in thermal contact with the collar, touching the collar or with a heat transfer medium interposed, such as heat transfer paste or the like. Appropriate cooling fins can be distributed relatively easily on the collar and connected to it. For example, they can be integrally formed with the collar by being welded or soldered to the collar or by being formed together with the base plate. Furthermore, it may be useful if the cooling fins are positioned vertically on the collar. This specifies a preferred embodiment for a cooling device, which is characterized in particular by the relatively low cost of manufacturing the cooling device and a high amount of heat that can be dissipated by convection.

It may also be useful to provide that the cooling device is formed by at least one fin block having a plate-like rear wall and cooling fins arranged over a surface area of the rear wall. The at least one fin block is advantageously a monolithic component, wherein its cooling fins are advantageously arranged parallel to each other and at equal distances from each other integrally on the surface area of the rear wall. At least one rib block, i.e., the rear wall and/or the cooling fins, is in thermal contact with the collar, either touching the collar or with a heat transfer medium, such as heat-conducting paste or similar, interposed between them. In particular, the at least one fin block can be integrally formed with the collar, for example by being welded or soldered to the collar or integrally molded with the base plate. Furthermore, it may be provided that the at least one fin block is arranged on the collar in such a way that the surface area of the rear wall of the at least one fin block equipped with the cooling fins is turned away from the housing of the stationary induction charging device. Furthermore, it may be advantageous if the cooling fins are positioned vertically on the surface area of the rear wall of at least one fin block. This provides a further preferred embodiment for a cooling device, which is characterized in particular by the relatively low cost of manufacturing the cooling device and its good heat dissipation capacity.

It may be expedient to provide that the rear wall has at least one of the following features:
it is formed from a flat and, in particular, cavity-free rectangular plate,
it is at least once angled, especially at right angles,
it is made of electrically conductive material, in particular aluminum, and is aligned with respect to the inductive charging device in such a way that it influences, in particular shields and/or guides, an electromagnetic field provided by an energy coil of the inductive charging device,
it is made of electrically conductive material, in particular aluminum, and is aligned with respect to a living object detection device of the stationary induction charging device, which is arranged in the housing and is designed to detect living objects located in particular in the vicinity of the stationary induction charging device, in such a way that that it influences, in particular shields and/or guides, an electromagnetic field provided by the living object detection device.
it is made of electrically conductive material, in particular made of an aluminum material, and is aligned with respect to a remote positioning device of the stationary induction charging device, which is arranged in the housing and is designed to guide the battery-powered vehicle to a target charging position, in such a way that it influences, in particular shields and/or guides, an electromagnetic field provided by the remote positioning device.
It is made of aluminum.

It may also be useful to provide that the cooling fins have at least one of the following features:
they taper from the point where they are connected to the collar or to the rear wall of the at least one fin block towards their free fin ends facing away from the point of connection, in particular they converge in a wedge-shaped, trapezoidal, or isosceles triangular shape,
they run from their point of connection with the collar or with the rear wall of at least one fin block to their free fin ends facing away from their point of connection, converging in a pointed corner or in a blunt or sharp-edged edge,
they are formed from a rectangular, trapezoidal, or triangular base,
they are made of electrically conductive material, in particular aluminum, and are aligned with respect to the inductive charging device in such a way that they influence, in particular shield and/or guide, an electromagnetic field provided by an energy coil of the inductive charging device,
they are made of electrically conductive material, in particular aluminum, and are aligned with respect to a stationary object detection device of the stationary induction charging device, which is arranged in the housing for detecting living objects located in the vicinity of the stationary induction charging device, for example between the stationary induction charging device and the vehicle-side induction charging device, so that they influence, in particular shield and/or guide, an electromagnetic field provided by the living object detection device of the stationary induction charging device.
they are made of electrically conductive material, in particular made of an aluminum material, and are aligned with respect to a remote positioning device of the stationary induction charging device, which is arranged in the housing and is designed to guide the battery-powered vehicle to a target charging position, in such a way that they influence, in particular shield and/or guide, an electromagnetic field provided by the remote positioning device.
They are made of aluminum.

The cooling fins can also be designed so that they meet IP69 protection class requirements with the housing of the stationary induction charging device, which describes a standard for all-round protection against dirt and moisture. Furthermore, the cooling fins can have a drainage slope on a side facing away from the ground so that water does not accumulate on them but can drain away.

It may be useful to provide that the base plate has a base surface on a side facing the lid which is divided into a mounting surface designed for fitting the inductive charging device and an edge strip surface surrounding the mounting surface and assigned to the collar. The inductive charging device and the lid are arranged on the mounting surface, with the lid completely spanning the inductive charging device. The cooling device is located on the edge strip surface of the collar, in particular without the interior space and in contact with the ambient air. In order to be able to dissipate heat well by convection using the cooling device, it may also be provided that the cooling device arranged on the edge strip surface is guided at least in sections or completely around the housing. For example, the cooling device completely or substantially completely encloses the housing.

It may also be useful to design the base plate as a rectangular block and the base surface as a quadrilateral, in particular a square or rectangle, with the edge strip surface comprising surface segments that each extend beyond one edge of the base surface. A first surface segment is located in the region of a cable bushing of the stationary induction charging device, opposite a third surface segment, and a second surface segment is located opposite a fourth surface segment. It is preferred that the cooling device is arranged only on the first, second, and fourth surface segments or on the first, second, third, and fourth surface segments. The first variant, in which the cooling device is arranged on the first, second, and fourth surface segments, is particularly suitable for a stationary induction charging device which, during operation of the inductive vehicle charging system, i.e., during a charging process, is arranged in the region of the front axle of the battery-electric vehicle. If the stationary induction charging device is located in the region under the rear axle of the battery-powered vehicle during operation of the inductive vehicle charging system, i.e., during a charging process, it may be advantageous if the cooling device is arranged on the first, second, third, and fourth surface segments in accordance with the further variant, so that the cooling device completely encloses the housing. In particular, to improve the manufacturability of the stationary induction charging device, it may be provided that corner region surfaces of the edge strip surface are free of the cooling device.

It may be useful to provide that the base plate has a base surface on a side facing the lid which is divided into a mounting surface designed for fitting the inductive charging device and an edge strip surface surrounding the mounting surface and assigned to the collar. Furthermore, the inductive charging device is arranged on the mounting surface and the lid is arranged on the mounting surface, the latter spanning the mounting surface and the inductive charging device. It is also planned that the cooling device is arranged on the edge strip surface of the collar, wherein the base surface, in particular its mounting surface or edge strip surface, defines a reference plane, wherein the inductive charging device comprises an energy coil and an arrangement of magnetic field conductors, preferably made of ferrite, associated therewith for guiding an electromagnetic field provided by the energy coil, wherein the magnetic field conductors span a plane which is spaced apart from and substantially parallel to the reference plane and is hereinafter referred to as the magnetic field conductor mirror. Furthermore, it is envisaged that the lid has an upper edge or surface on a side of the lid facing away from the base surface, which spans a plane that is spaced apart from and essentially parallel to the reference plane and is subsequently referred to as the lid mirror, wherein the cooling device, in particular a rear wall and/or cooling fins thereof, has a maximum height in a height direction perpendicular to the reference plane, wherein the maximum height of the cooling device is less than a straight-line distance between the reference plane and the lid mirror and/or the maximum height of the cooling device is less than a straight-line distance between the reference plane and the magnetic field conductor mirror. In the case of magnetic field conductors arranged in a three-dimensional structure, the magnetic field conductor plane is conveniently defined by the height perpendicular to the reference plane, which is determined by the arithmetic mean of the individual distances in the height direction between the magnetic field conductors and the reference plane. This optimally adapts the cooling device to the inductive charging device, in particular preventing losses such as eddy current losses. In particular, this allows for relatively low dispersion of the electromagnetic field in question.

According to a further basic idea of the invention, an inductive vehicle charging system is provided for charging a battery-powered vehicle with electrical energy, which is equipped with a stationary induction charging device that can be fixedly arranged on a ground in accordance with the above description.

To summarize, it remains to be said: The present invention relates preferably to a stationary induction charging device for an inductive vehicle charging system, which has a housing comprising a base plate and a lid arranged thereon, wherein the base plate has a collar which projects beyond the lid. The stationary induction charging device also has an inductive charging device which is arranged within an interior space of the housing bounded by the base plate and the lid in thermal contact with the base plate and is designed for electromagnetic interaction with an induction charging device assigned to the battery-electric vehicle, so that electrical energy can be transferred from the stationary induction charging device to the battery-powered vehicle and vice versa, as well as a cooling device thermally contacted to the collar and designed to convectively dissipate heat energy from the base plate to the ambient air of the stationary induction charging device. The invention relates in particular to an inductive vehicle charging system with such a stationary induction charging device.

Further important features and advantages of the invention are apparent from the dependent claims, from the drawings, and from the associated description of the figures with reference to the drawings.

It is understood that the above-mentioned features and those yet to be explained below can be used not only in the combination indicated in each case, but also in other combinations or on their own, without deviating from the scope of the present invention.

Preferred embodiments of the invention are shown in the drawings and are explained in more detail in the following description, wherein identical reference signs refer to identical or similar or functionally identical components.

They show, schematically in each case

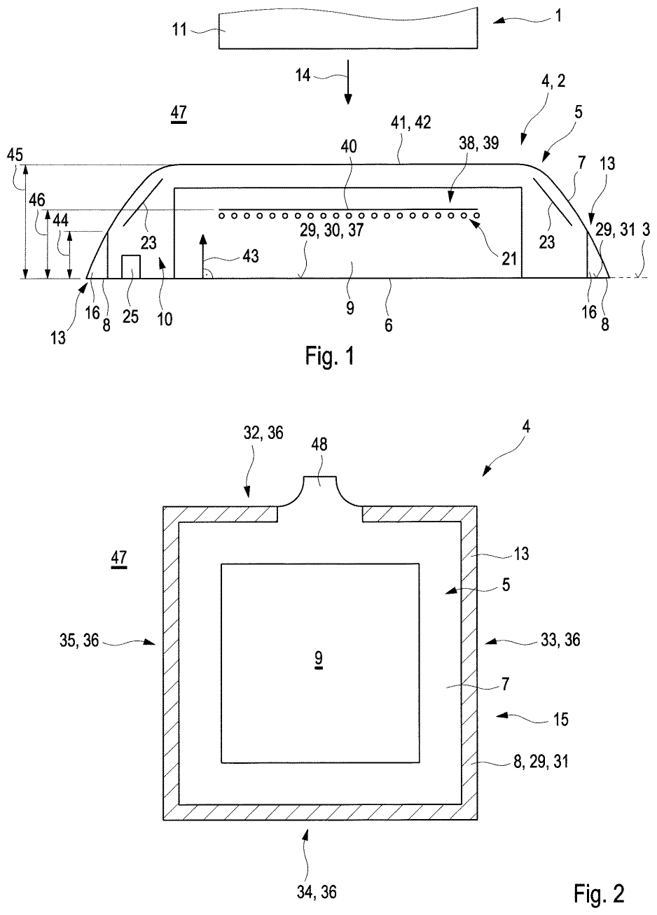

FIG. 1 shows a first embodiment of a stationary induction charging device for an inductive vehicle charging system designed to charge a battery-powered vehicle with electrical energy, in a side view, wherein the stationary induction charging device arranged on a ground is cut away for the sake of clarity of the explanations.

FIG. 2 through 5 show further embodiments of a stationary induction charging device in a top view.

FIGS. 6 and 7 show a preferred embodiment of a cooling device in a perspective view.

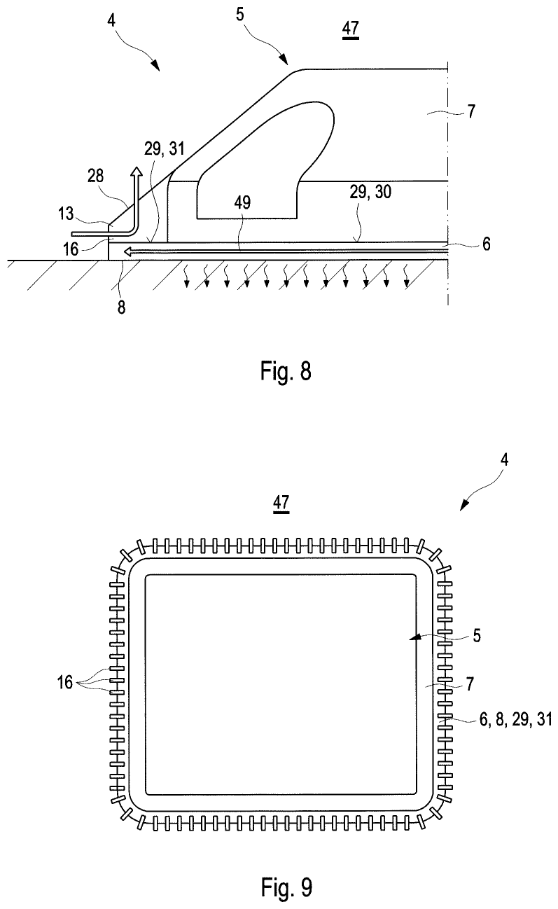

FIGS. 8 and 9 show another embodiment of a stationary induction charging device in a side view and a top view, respectively, and finally

FIGS. 1 through 9 show preferred embodiments of a stationary induction charging device, designated as a whole by reference numeral 4, for an inductive vehicle charging system 2 designed to charge a battery of a battery-electric vehicle 1 with electrical energy. The stationary induction charging device 4 is shown as an example on a flat ground 3, such as the floor of a garage or parking lot, and is fixed in position. It has a central housing 5 with a flat base plate 6 and a dome-shaped lid 7 centered on the base plate. The base plate 6 and the lid 7 thereby delimit an interior space 10 of the housing 5, in which various components of the stationary induction charging device 4 are arranged for protection against environmental influences. The base plate 6 has or forms a collar 8 which protrudes horizontally in front of the lid 7 and surrounds the latter at least in sections in a rim-like manner. The stationary induction charging device 4 further comprises an inductive charging device 9, which is placed within the interior space 10 of the housing 5 and arranged on the base plate 6 in such a way that it is at least in thermal contact, i.e., thermally connected, with the base plate 6. It is touchingly supported on the base plate 6. In addition, the inductive charging device 9 is designed for electromagnetic interaction with an induction charging device 11 assigned to the battery-powered vehicle 1, so that during operation of the inductive vehicle charging system 2, electrical energy can be transferred from the stationary induction charging device 4 to the battery-powered vehicle 1 and vice versa. As an example, it is provided that the base plate 6 has a flat base surface 29 on a side facing the lid 7, which is divided into a mounting surface 30 set up for mounting the inductive charging device 9, i.e., at least for establishing a thermal contact, and an edge strip surface 31 framing the mounting surface 30 and assigned to the collar 8 and facing away from the base 3. The inductive charging device 9 and the lid 7 are arranged on the mounting surface 30.

During operation of the inductive vehicle charging system 2, losses in the form of heat occur in particular at the inductive charging device 9, which is conducted in particular into the base plate 6 and from there in particular via the collar 8 by convection to the ambient air on the one hand and by heat conduction to the ground 3 on the other hand, so that relatively effective temperature control of the stationary induction charging device 4 is achieved. The proportion of the dissipatable heat output that can be dissipated by convection is proportional to the temperature difference between the base plate 6 on the one hand and the ambient air 47 and the ground 3 on the other. Accordingly, as the ambient temperature rises and the temperature difference between the base plate 6, the ambient air 47, and the ground 3 decreases, the heat that can be dissipated continuously decreases, which, especially at high ambient temperatures, poses a risk of overheating the stationary induction charging device 4 and thus destroying it. To avoid this, when a predetermined transmission power is requested by the user from the stationary induction charging device 4 and a certain ambient temperature is reached or exceeded, the transmission power of the inductive charging device 9 is currently reduced. This results in less heat loss in the stationary induction charging device 4, so that, given the heat dissipation capacity, overheating of the stationary induction charging device 4 can be avoided. However, due to the reduced transmission power, less electrical energy can be transferred from the stationary induction charging device 4 to the battery of the battery-electric vehicle 1, i.e., to the vehicle-side induction charging device 11. This increases the charging time required to charge the battery electric vehicle 1, which reduces customer comfort when charging the battery electric vehicle 1 due to longer waiting times.

To overcome these disadvantages, it is planned that the stationary induction charging device 4 is equipped with a cooling device 13 made of electrically conductive material, in particular aluminum, which is designed to convectively dissipate heat from the base plate 6 and/or the collar 8 to the ambient air 47 and is at least thermally in contact with the collar 8, i.e., thermally connected.

According to the embodiment illustrated in FIG. 1, it is provided that the cooling device 13 is supported in contact with the edge strip surface 31 of the collar 8 facing away from the ground 3, which is located without the interior space 10 in contact with the ambient air 47. This results in the operation of the inductive vehicle charging system 2, exemplified in FIGS. 8 and 9, which is followed by a heat flow based on heat conduction, which extends from the inductive charging device 9, which is regarded here as the heat source, through the base plate 6, into the collar 8 of the base plate 6 and then into the cooling device 13. This can then release heat convectively to the ambient air 47, thereby increasing the amount of heat that can be dissipated per unit of time and thus achieving improved temperature control of the stationary induction charging device 4. This allows the inductive vehicle charging system 2 to operate even at higher ambient temperatures without reducing the transmission power, ultimately increasing customer comfort.

With reference to FIG. 1, it should also be explained that the inductive charging device 9 of the stationary induction charging device 4 has, for example, a flat energy coil 21 which provides an electromagnetic field for electromagnetic interaction with the induction charging device 11 assigned to the battery-powered vehicle 1. The energy coil 21 is assigned an arrangement 38 of separate magnetic field conductors 39, which are preferably made of ferrite and are designed to guide the magnetic field of the energy coil 21. The stationary induction charging device 4 is also equipped with a live object detecting device 23 arranged to detect live objects located in the vicinity of the stationary induction charging device 4, for example between the stationary induction charging device 4 and the vehicle-side induction charging device 11, and a remote positioning device 25 arranged to bring the battery electric vehicle 1 to a target charging position at the stationary induction charging device 4. Furthermore, the inductive vehicle charging system 2 may comprise power electronics not illustrated here, which are either housed in the inductive charging device 9 or alternatively in a device of the inductive vehicle charging system 2 that is separate from the stationary induction charging device 4.

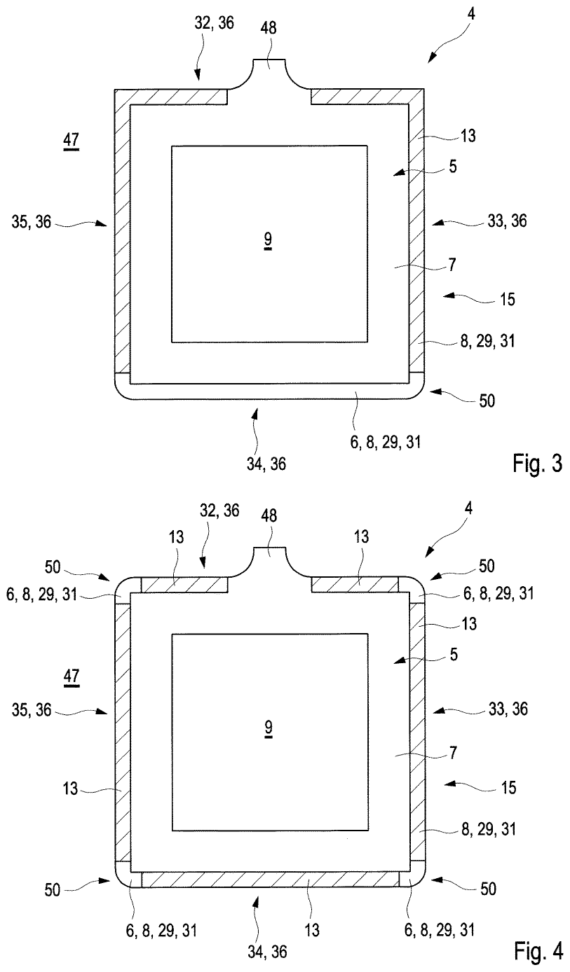

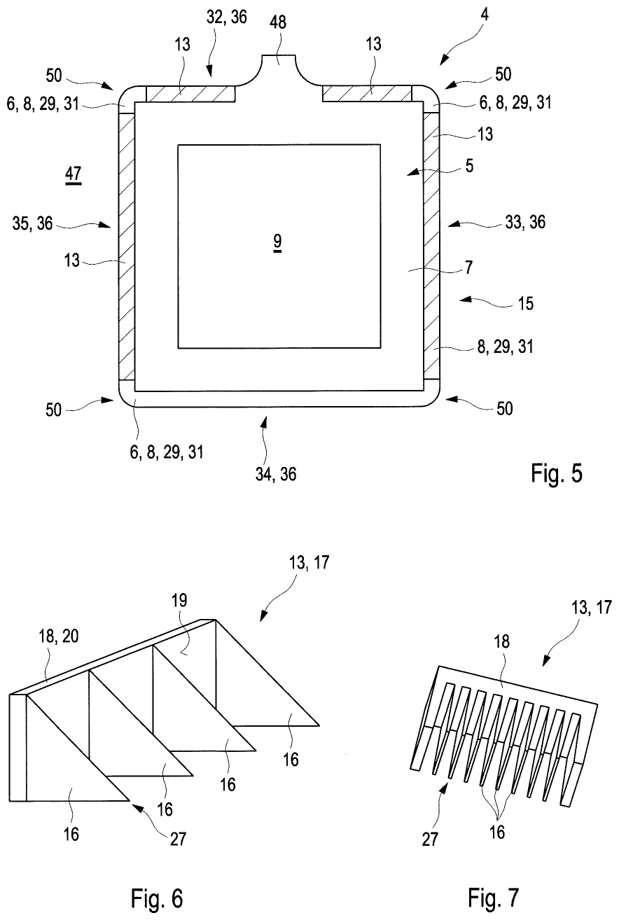

FIGS. 2 through 5 show that the base plate 6 is exemplarily cuboid and the base surface 29 is quadrangular. In this case, the edge strip surface 31 has associated surface segments 32, 33, 34, 35, each of which extends completely over an edge 36 of the base surface 29. A first surface segment 32 is located in the region of a cable bushing 48 of the stationary induction charging device 4 and is opposite a third surface segment 34. Furthermore, a second surface segment 33 is opposite a fourth surface segment 35. The first surface segment 32 is parallel to the third surface segment 34. The second surface segment 33 is parallel to the fourth surface segment 35. The first surface segment 32 and the third surface segment 34 are each at right angles to the second surface segment 33 and the fourth surface segment 35. The surface segments 32, 33, 34, 35 thereby define a frame which surrounds the mounting surface 29 in the present case. According to the embodiment illustrated in FIG. 2, the cooling device 13 is arranged on all four surface segments 32, 33, 34, 35. The cooling device 13 completely encloses the housing 5 and the inductive charging device 9 in a frame-like manner. The cooling device 13 therefore has an approximately square-ring-shaped contour 15 when viewed in a perpendicular direction 14 towards the base plate 6, wherein the first surface segment 32 excludes a region for the cable bushing 47. This enables particularly good convective cooling performance to be achieved. According to the embodiment illustrated in FIG. 3, it is provided that the cooling device 13 is arranged only on the first surface segment 32, the second surface segment 33, and the fourth surface segment 35. As a result, the cooling device 13 has an approximately U-shaped contour 15 when viewed in a perpendicular direction 14 towards the base plate 6, with a region for the cable bushing 47 being recessed in the first surface segment 32. The embodiment illustrated in FIG. 4 corresponds to the embodiment in FIG. 2, with the exception that, in order to improve the manufacturability of the stationary induction charging device, four corner region surfaces 50 of the edge strip surface 31 are free of the cooling device 13. The embodiment illustrated in FIG. 5 corresponds to the embodiment in FIG. 3, except that, again to improve the manufacturability of the stationary induction charging device 4, corner region surfaces 50 of the edge strip surface 31 are free of the cooling device 13. The embodiments according to FIGS. 3 and 5, in which the cooling device 13 is arranged on the first, second, and fourth surface segments 32, 33, 35, are particularly suitable for cases in which, during operation of the inductive vehicle charging system 2, the stationary induction charging device 4 is arranged in the region of a front axle of the battery-electric vehicle 1. If the stationary induction charging device 4 is arranged in the region under a rear axle of the battery-electric vehicle 1 during operation of the inductive vehicle charging system 2, it may be advantageous if the cooling device 13 is arranged on the first, second, third, and fourth surface segments 32, 33, 34, 35 according to the embodiments illustrated in FIGS. 2 and 4.

FIGS. 6 through 9 show preferred embodiments of the cooling device 13, wherein, according to FIGS. 8 and 9, the cooling device 13 is formed by separate cooling fins 16. The cooling fins 16 are arranged, for example, parallel to one another and at equal distances from one another in thermal contact with the collar 8 on the collar 8 on its edge strip surface 31, wherein they are perpendicular to the collar 8. The cooling fins 16 are, for example, integrally formed with the collar 8.

According to FIGS. 6 and 7, the cooling device 13 is formed by at least one fin block 17, which has a plate-like rear wall 18 and cooling fins 16 arranged on a surface area 19 of the rear wall 18. The at least one fin block 17 is, for example, a monolithic component, wherein its cooling fins 16 are conveniently arranged parallel to each other and at equal distances from each other integrally on the surface area 19 of the rear wall 18. At least one fin block 17, i.e., its rear wall 18 and cooling fins 16, is arranged in thermal contact with the collar 8 on the collar 8 on its edge strip surface 31, wherein the rear wall 18 faces the housing 5 and the cooling fins 16 face away from the housing 5. The rear wall 18 can also be characterized in that it is formed by a flat and, in particular, cavity-free rectangular plate 20. In addition, it can be bent at least once, especially at right angles. Furthermore, it is conceivable that it is made of electrically conductive material, in particular aluminum, and is aligned with respect to the inductive charging device 9 in such a way that it influences, in particular shields and/or guides, the electromagnetic field provided by the energy coil 21 and/or the electromagnetic field provided by the living object detection device 23 and/or the electromagnetic field provided by the remote positioning device 25.

The cooling fins 16 described above, as shown in FIGS. 6 through 9, is that they taper from the point where they are connected to the collar 8 or the rear wall 18 to their free fin ends 27 facing away from the point of connection; in particular, they converge in a wedge-shaped, trapezoidal, or isosceles triangular shape. Furthermore, these cooling fins 16 are characterized in that they converge from their point of connection with the collar 8 or with the rear wall 18 toward their free fin ends 27, which are located away from their point of connection, to form a pointed corner or a blunt, sharp-edged edge 28 that is inclined relative to the base plate 6. The cooling fins 16 can also be formed by a rectangular, trapezoidal, or triangular base body. It is also conceivable that the cooling fins 16 are made of electrically conductive material, in particular aluminum, and are aligned with respect to the inductive charging device 9 in such a way that they influence, in particular shield and/or guide, the magnetic field provided by the energy coil 21 and/or the electromagnetic field provided by the living object detection device 23 and/or the electromagnetic field provided by the remote positioning device 25.

In order for the cooling device 13 to be optimally adapted to the inductive charging device 9, the living object detection device 23, and the remote positioning device 25, it may be provided, for example, the base surface 29, in particular its mounting surface 30 or edge strip surface 31, defines a reference plane 37, the magnetic field conductors 39 of the arrangement 38 define a second plane, referred to as a magnetic field conductor mirror 40, which is spaced apart from and parallel to the reference plane 37, and the lid 7 defines a third plane, which is spaced apart from and parallel to the reference plane 37 and parallel to the reference plane 37, which is spanned or applied to a side of the lid 7 facing away from the base surface 29 at a lid upper edge or surface 41 of the lid 7 and is referred to as a lid mirror 42. At least according to FIG. 1, it is intended that the cooling device 13, in particular the rear wall 18 and/or the cooling fins 16 mentioned above, have a maximum height 44 in a height direction 43 perpendicular to the reference plane 37, which is 1) is less than a straight-line distance 45 between the reference plane 37 and the lid mirror 42 and 2) is less than a straight-line distance 46 between the reference plane 37 and the magnetic field conductor mirror 40.

1. A stationary induction charging device that can be arranged in a fixed position on a flat ground for an inductive vehicle charging system designed to charge a battery of a battery-electric vehicle, comprising:
a housing including a base plate and a lid arranged thereon, the base plate including a collar which projects beyond the lid and extends around the lid at least in sections;
an inductive charging device arranged within an interior space of the housing bounded by the base plate and the lid in thermal contact with the base plate, the inductive charging device configured for electromagnetic interaction with an induction charging device assigned to the battery-electric vehicle, such that electrical energy is transferable inductively from the stationary induction charging device to the battery-electric vehicle and vice versa; and
a cooling device structured and arranged to convectively dissipate heat energy from the base plate to ambient air in thermal contact with the collar.

2. The stationary induction charging device according to claim 1, wherein the cooling device is arranged in contact with the collar directly and/or via a heat transfer medium interposed therebetween.

3. The stationary induction charging device according to claim 1, wherein the cooling device is composed of an electrically conductive material.

4. The stationary induction charging device according to claim 1, wherein the cooling device has a contour that is rectangular, L-shaped, rectangular ring-shaped, and/or square ring-shaped when viewed in a perpendicular direction towards the base plate.

5. The stationary induction charging device according to claim 1, wherein the cooling device is formed by a plurality of cooling fins.

6. The stationary induction charging device according to claim 1, wherein the cooling device is formed by at least one fin block including a plate-like rear wall and a plurality of cooling fins arranged on a surface area of the rear wall.

7. The stationary induction charging device according to claim 6, wherein the rear wall is a flat, cavity-free rectangular plate.

8. The stationary induction charging device according to claim 6, wherein the plurality of cooling fins are each formed from a rectangular, trapezoidal, or triangular base body.

9. The stationary induction charging device according to claim 1, wherein:
the base plate has a base surface on a side facing the lid;
the base surface is divided into i) a mounting surface for assembly with the inductive charging device and ii) an edge strip surface framing the mounting surface and assigned to the collar;
the inductive charging device and the lid are arranged on the mounting surface;
the lid spans the mounting surface and the inductive charging device; and
the cooling device is arranged on the edge strip surface.

10. The stationary induction charging device according to claim 9, further comprising a cable bushing, wherein:
the base plate is rectangular and the base surface is quadrangular;
the edge strip surface includes a plurality of surface segments which each extend over an edge of the base surface, the plurality of surface segments including a first surface segment, a second surface segment, a third surface segment, and a fourth surface segment;
the first surface segment is arranged in a region of the cable bushing and is opposite the third surface segment;
the second surface segment is opposite the fourth surface segment; and
the cooling device is arranged on:
the first surface segment, the second surface segment, and the fourth surface segments; and/or
the first surface segment, the second surface segment, the third surface segment, and the fourth surface segments.

11. The stationary induction charging device according to claim 9, wherein:
the base surface defines a reference plane;
the inductive charging device includes an energy coil and an arrangement of magnetic field conductors assigned thereto for guiding an electromagnetic field provided by the energy coil;
the arrangement of magnetic field conductors spans a magnetic field conductor mirror plane arranged at a distance from and parallel to the reference plane;
the lid has, on a side facing away from the base surface, a lid upper surface spanning a lid mirror plane that is disposed spaced apart from and parallel to the reference plane;
the cooling device has a maximum height in a height direction extending perpendicular to the reference plane;
the maximum height of the cooling device is smaller than a straight-line distance between the reference plane and the lid mirror plane; and
the maximum height of the cooling device is smaller than a straight-line distance between the reference plane and the magnetic field conductor mirror plane.

12. An inductive vehicle charging system configured to charge a battery-electric vehicle with electrical energy, comprising the stationary induction charging device according to claim 1.

13. The stationary induction charging device according to claim 6, wherein:
the inductive charging device includes an energy coil; and
the rear wall and/or at least one cooling fin of the plurality of cooling fins is aligned with respect to the inductive charging device such that the rear wall and/or the at least one cooling fin shields and/or guides an electromagnetic field provided by the energy coil of the inductive charging device.

14. The stationary induction charging device according to claim 6, further comprising a living object detection device configured to detect living objects in the stationary induction charging device, wherein:
the living object detection device is arranged in the housing; and
the rear wall and/or at least one cooling fin of the plurality of cooling fins is aligned with respect to the living object detection device such that the rear wall and/or the at least one cooling fin shields and/or guides an electromagnetic field provided by the living object detection device.

15. The stationary induction charging device according to claim 6, further comprising a remote positioning device configured to guide the battery-electric vehicle to a target charging position, wherein:
the remote positioning device is arranged in the housing; and
the rear wall and/or at least one cooling fin of the plurality of cooling fins is aligned with respect to the living object detection device such that the rear wall and/or the at least one cooling fin shields and/or guides an electromagnetic field provided by the remote positioning device.

16. The stationary induction charging device according to claim 6, wherein the rear wall and/or the plurality of cooling fins are composed of an electrically conductive material.

17. The stationary induction charging device according to claim 16, wherein the electrically conductive material is aluminum.

18. The stationary induction charging device according to claim 6, wherein the rear wall is angled and includes a plurality of wall sections extending transversely relative to one another.

19. The stationary induction charging device according to claim 6, wherein each cooling fin of the plurality of cooling fins is connected to the collar and/or the rear wall, has a free end disposed opposite the collar and/or the rear wall, and tapers toward the free end such that the cooling fin has a wedge-shaped, trapezoidal, or isosceles triangular shaped profile.

20. The stationary induction charging device according to claim 6, wherein each cooling fin of the plurality of cooling fins is connected to the collar and/or the rear wall, has a free end disposed opposite the collar and/or the rear wall, and has a pointed corner, a blunt edge, and/or a sharp-edged edge that extends from the collar and/or the rear wall to the free end transversely to the base plate.
